(19) United States
(12) Patent Application Publication
(10) Pub. No.: US 2010/0262392 A1
(43) Pub. Date: Oct. 14, 2010

(54) SYSTEM AND METHOD FOR IMPLEMENTING DATA STORAGE MODES IN A DATA STORAGE SYSTEM

(75) Inventors: Robert Dale Murphy, Boulder, CO (US); Vincent Michael McGarry, Longmont, CO (US); Matthew John Schwall, Longmont, CO (US)

Correspondence Address: SEAGATE TECHNOLOGY LLC;C/O WESTMAN, CHAMPLIN & KELLY, P.A., SUITE 1400, 900 SECOND AVENUE SOUTH, MINNEAPOLIS, MN, 55402-3244, US

(73) Assignee: Seagate Technology LLC, Scotts Valley, CA (US)

(21) Appl. No.: 12/422,721

(22) Filed: Apr. 13, 2009

(51) Int. Cl. G01R 31/36

(52) U.S. Cl. 702/63

(57) ABSTRACT

The present disclosure provides a data storage system configured to implement data storage modes based on a battery health indicator. In one embodiment, a data storage system is provided and comprises an input interface configured to receive data and the battery health indicator. In one example, the data and battery health indicator is received from a host system through the input interface. The data storage system also includes at least one data storage device and a controller configured to store data in the at least one data storage device. The controller is configured to implement a data storage mode based on the battery health indicator.

### BACKGROUND

The present disclosure relates generally to data storage systems and more specifically, but not by limitation, to implementing data storage modes in a data storage system.

An exemplary data storage system includes a device having at least one medium for data storage. The data storage system can include one or more types of storage mediums such as, but not limited, to hard discs, floppy discs, magnetic discs, optical discs, magnetic tapes, solid-state storage components, and/or combinations thereof. For instance, an exemplary data storage system can comprise a hard disc drive (HDD), a solid-state drive (SDD), a “hybrid” drive (e.g., a hybrid hard drive (HHD)), to name a few. The data storage system includes a controller that is configured to receive data and commands from a host and implement data operations to the storage media in the data storage device based on the commands.

In one example, the data storage system is powered by an exhaustible power source, such as a battery. For instance, in one particular application a data storage system is implemented in a laptop or notebook computer. In another example, a data storage system is implemented in a mobile computing device such as a personal data assistant (PDA), mobile phone, etc.

The discussion above is merely provided for general background information and is not intended to be used as an aid in determining the scope of the claimed subject matter.

### SUMMARY

The present disclosure provides a data storage system configured to implement data storage modes based on a battery health indicator. In one embodiment, a data storage system is provided and comprises an input interface configured to receive data and the battery health indicator. In one example, the data and battery health indicator is received from a host system through the input interface. The data storage system also includes at least one data storage device and a controller configured to store data in the at least one data storage device. The controller is configured to implement a data storage mode based on the battery health indicator.

In one exemplary embodiment, a controller in a data storage system is provided and includes an input configured to receive data and a battery health indicator from a host device. The battery health indicator is indicative of a level of power in an exhaustible power source. The controller also includes a processing component configured to adjust a data storage mode based on the battery health indicator received from the host device and an output configured to provide the data to at least one data storage component based on the data storage mode.

In one exemplary embodiment, a method for storing data in a data storage system is provided and includes receiving an indication from a host device of a level of power in an exhaustible power source and implementing a data storage mode based on the indication. The method also includes receiving data from the host device and storing the data to at least one data storage medium in the data storage system based on the data storage mode.

These and various other features and advantages will be apparent from a reading of the following Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

FIG. 1 is a schematic diagram of an exemplary data storage system.

FIG. 2A is a schematic diagram of a data storage system, under one embodiment.

FIG. 2B is a schematic diagram of a data storage system, under one embodiment.

FIG. 3 is a flow diagram of a method of implementing data storage modes.

FIG. 4 is a flow diagram of a method of implementing data storage modes.

### DETAILED DESCRIPTION

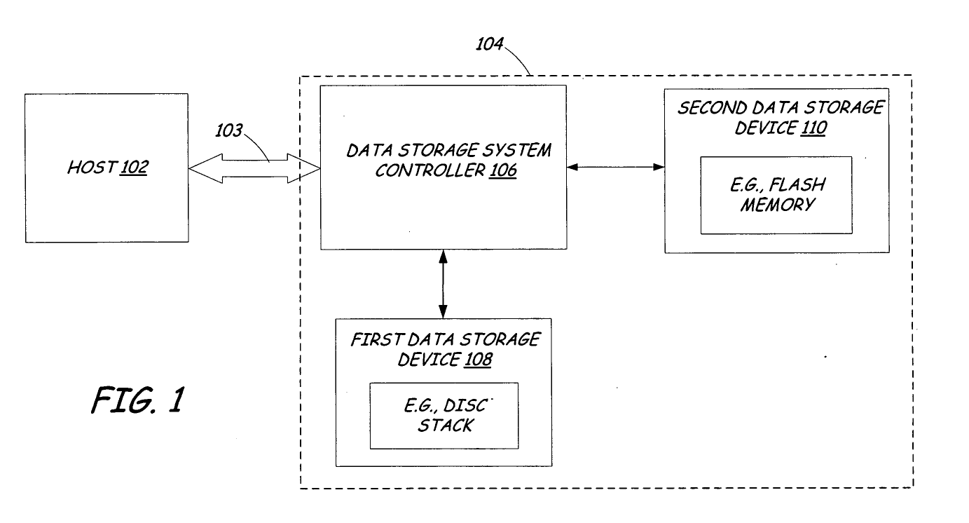

FIG. 1 is a schematic diagram of an exemplary data storage system 104 that includes at least one data storage device. In the illustrated embodiment, data storage system 104 is communicatively coupled to a host 102. Host 102 can include any device, component, system, sub-system, application, and the like, that communicates (e.g., sends, receives, accesses, requests, processes data) with data storage system 104. In one example, host 102 comprises a computing device such as, but not limited to, a personal computer, laptop computer, server, portable electronic device, mobile device, digital music player, mobile phone, personal digital assistant (PDA), to name a few. It is noted that data storage system 104 can be included within or can be external to host 102. For example, in one embodiment data storage system 104 comprises a data storage drive, such as, but not limited to, a hard disc drive (HDD), a solid-state drive (SDD), a “hybrid” drive (e.g., a hybrid hard drive (HHD)), and the like, that is coupled to the host 102 using any suitable type of data connection.

Data storage system 104 includes a controller 106 that is configured to communicate with the host 102 through a data channel 103. As illustrated in FIG. 1, data storage system 104 includes a first data storage device 108 and a second data storage device 110. Controller 106 is configured to store data to and read data from storage devices 108 and 110.

In the illustrated embodiment, data storage device 108 includes storage media configured for persistent and/or long-term data storage. Examples of storage media in device 108 include, but are not limited to, a disc stack having one or more data storage discs. However, it is noted that in other embodiments data storage device 108 can include any suitable type of memory components) such as other forms of non-volatile memory as well as volatile memory. Some examples include, but are not limited to, floppy discs, magnetic discs, optical discs, magnetic tapes, and solid-state storage components, to name a few.

Data storage device 110 also includes storage media configured to store data. In the illustrated embodiment, data storage device 110 comprises a different type of media and/or is separate (e.g., physically spaced) from device 108. Further, device 110 can be configured for intermediate data storage (e.g., a data buffer, a data cache). Alternatively, or in addition, data storage device 110 can be configured for persistent and/or long-term data storage. For example, data storage device 110 can include non-volatile data memory devices as well as volatile data memory devices.

In the embodiment illustrated in FIG. 1, data storage device 110 comprises a non-volatile solid-state memory, illustratively flash memory. However, while device 110 is described herein with respect to flash memory, it is noted that in other embodiments data storage device 110 can include other forms of memory. Examples include, but are not limited to, hard discs, floppy discs, magnetic discs, optical discs, magnetic tapes, electrically erasable programmable read-only memory (EEPROM), non-volatile random access memory (NVRAM), and other forms of solid-state storage components, to name a few.

In accordance with one embodiment, a data storage system is configured to implement data storage (or data retrieval) modes based on a state of a power source. In one example, the data storage system implements particular data storage modes to manage power usage of the data storage system. In another example, the data storage system implements particular data retrieval modes to manage power usage of the data storage system. Different data storage (or retrieval) modes have different power consumption characteristics and power requirements. In one embodiment, a data storage system includes multiple storage mediums that have different operating power requirements.

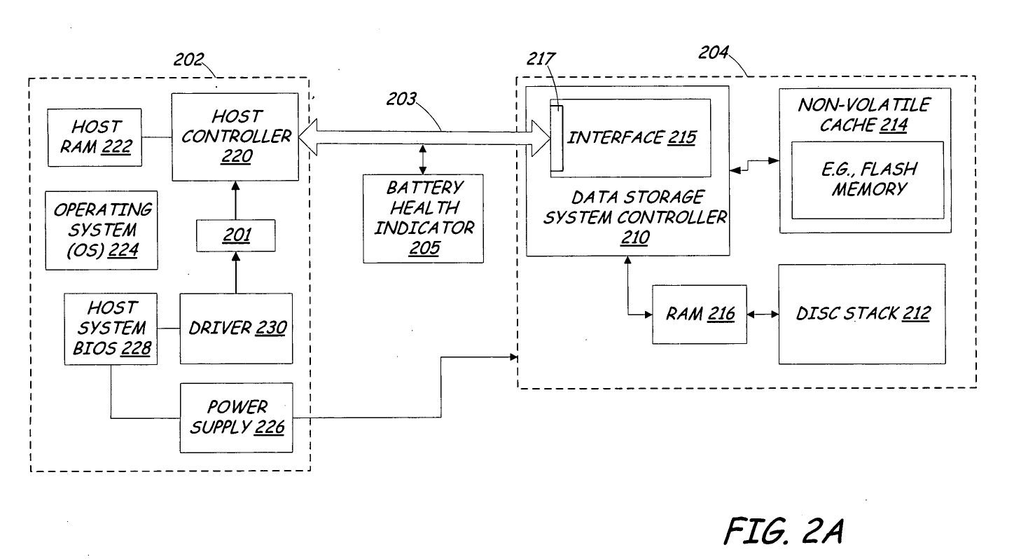

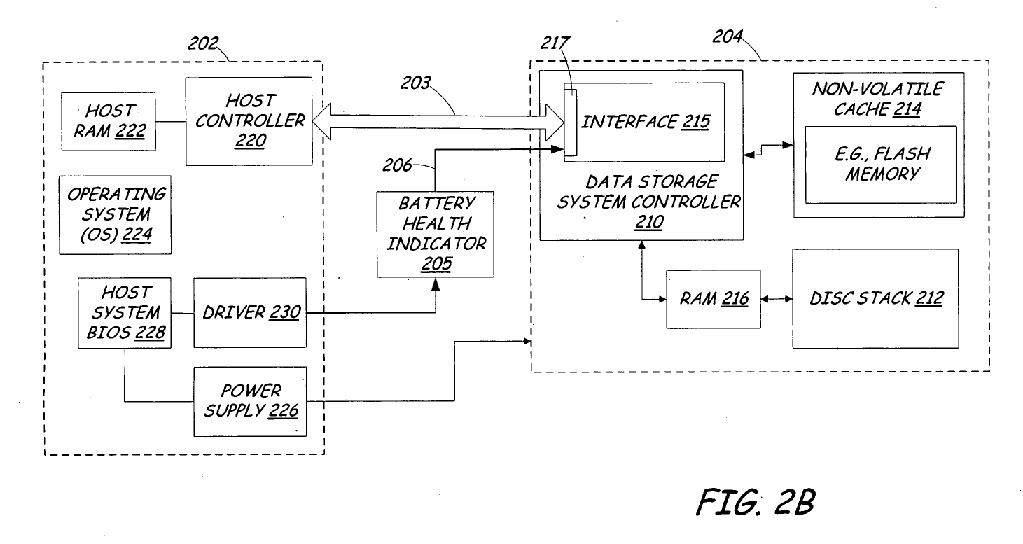

FIG. 2A is a schematic diagram of a data storage system 204 that includes at least one data storage device. Data storage system 204 is communicatively coupled to a host 202. In one embodiment, host 202 is similar to host 102 and can include any device, component, system, sub-system, application, and the like that communicates with data storage system 204. In one example, host 102 comprises a computing device such as, but not limited to, a laptop computer, a personal computer, a portable electronic device, a mobile device, to name a few.

Data storage system 204 includes a data storage system controller 210 having an interface 215 for receiving data and commands from host 202 over a communication channel 203. Communication channel 203 comprises any suitable type of channel including, but not limited to, parallel and serial computer buses. In the illustrated embodiment, channel 203 comprises a serial ATA (SATA) computer bus providing a storage-interface for connecting a host bus adapter of host 202 with data storage system 204. In this example, using standard SATA commands (i.e., a standard SATA command structure), host 202 can communicate commands (i.e., write commands, read commands, seek commands, calibrate commands, flush commands, etc.), address information, and/or user data over SATA bus 203 to controller 210. Interface 215 comprises a SATA interface 217 having a plurality of pins for connecting SATA bus 203.

Data storage system controller 210 is configured to receive the commands and data over channel 203 and implement data storage modes for storing the data to storage media in data storage system 204. Further, data storage system controller 210 is also configured to receive data access commands (e.g., read commands) and/or address information and access data stored on media in the data storage system 204. The controller 210 provides the read data to host 202 over channel 203.

As illustrated in FIG. 2A, data storage system 204 includes a first data storage device 212 having a first data storage medium and a second data storage device 214 having a second data storage medium. In the embodiment of FIG. 2A, data storage devices 212 and 214 are similar to data storage devices 108 and 110, respectively, illustrated in FIG. 1. Data storage system 204 also includes random-access memory (RAM) 216 that provides a buffer or cache for writing to or reading data from disk stack 212. RAM 216 can comprise volatile or non-volatile memory.

As illustrated in FIG. 2A, host 202 comprises a host controller 220 that communicates with data storage system 204 over communication channel 203. Host 202 can also include host RAM 222 and an operating system 224 providing an interface between applications and hardware of host 202. For instance, operating system 224 can provide a number of services to application programs and users through application programming interfaces (APIs) or system calls, for example.

In the embodiment illustrated in FIG. 2A, host 202 includes a power supply 226 that is configured to supply power to components of host 202. As illustrated, power supply 226 is also configured to provide power to data storage system 204. In the embodiment of FIG. 2A, power supply 226 comprises an exhaustible power supply, such as a battery.

Host 202 can also include a host system BIOS (Basic Input/Output System) 228. In one example, BIOS programs are stored on a chip and are designed to work with various devices and components of host 202. Host system BIOS 228 provides boot firmware, for example, for identifying, testing, and initializing devices and components of host 202. Host system BIOS 228 can also provide functions related to power management, thermal management, etc.

As illustrated in FIG. 2A, data storage system 204 is configured to receive a battery health indicator 205 from host 202. Battery health indicator 205 provides information regarding a status or operational state of power supply 226. For example, battery health indicator 205 can comprise an indication of a percentage of power remaining in exhaustible power source 226. In another example, battery health indictor 205 can comprises an indication of an estimated amount to time before exhaustible power source 226 is drained. In another example, battery health indictor 205 can comprises an indication of an amount of charge or energy in power source 226. In another example, battery health indictor 205 can comprises an indication of a voltage level of power source 226.

In the embodiment illustrated in FIG. 2A, battery health indicator 205 is transmitted from host 202 over channel 203. For example, battery health indicator 205 is received at one or more pins of SATA interface 217 over SATA communication bus 203. In this manner, battery health indicator 205 can be transmitted to device 204 over the same physical interface as other commands and user data. Further, battery health indicator 205 can be transmitted with, or separately from, other commands and/or data transmitted over communication bus 203. For instance, in one example battery health indicator 205 is transmitted by controller 220 separately and/or independently from other commands sent from host 202 to data storage system 204.

In accordance with one embodiment, battery health indicator 205 is transmitted over a SATA bus 203 to SATA interface 217 of controller 210 using special or “vendor unique” commands. The special or “vendor unique” commands can have a different or unique command structure than a set of standard SATA commands used to send other commands (i.e., data read commands, data write commands, etc.) and/or user data to device 204. In one embodiment, a vendor unique command comprises a “pass through” command that is utilized to pass the battery health indicator 205 through controller 220 over bus 203. In one example, the “pass through” command operates to pass battery health information 201 through controller 220 independent of other commands associated with controller 220. In one embodiment, information 201 comprises battery health indicator 205. In another embodiment, information 201 can comprises other information pertaining to power supply 226. For example, controller 220 can be configured to generate indicator 205 based on the information 201.

In accordance with one embodiment, host 202 includes a battery-monitoring feature that provides battery health information 201. In the illustrated embodiment, host 202 includes a driver 230 that is configured to provide battery health information 201 to controller 220. Driver 230 can comprise one or more drivers that are separate from operating system 224. In another embodiment, driver 230 can comprise a device driver of operating system 224. For instance, a software application of host 202 installs a device driver 230. The device driver 230 is configured to filter operating system messages to identify messages that apply to power modes.

In one embodiment, the device driver 230 is configured to filter operating system messages to identify messages that include power information associated with power supply 226. For instance, driver 230 can be configured to filter only operating system messages that include information pertaining to, for example, a charge or energy of the power source 226, a percentage of power remaining in power supply 226, and/or a remaining discharge time or rate of power supply 226, to name a few. Further, driver 230 can be configured to identify messages pertaining to power modes associated with operating system 224 and/or a switch between AC power and battery power. The power information identified by driver 230 can comprise the information 201 provided to controller 220. In another example, a software application can install a device driver 230 that utilizes a polling mechanism configured to periodically make requests to the operating system 224 and/or BIOS 228 for power information.

It is noted that while FIG. 2A illustrates a device driver 230, in one embodiment the battery information 201 can be provided to controller 220 directly from host system BIOS 228 and/or operating system 224.

In accordance with one embodiment, data storage system controller 210 is configured to implement or adjust a data storage mode based on the battery health indicator 205 received from host 202. For example, controller 210 is configured to select a particular data storage mode from a plurality of data storage modes.

Further, controller 210 can implement a data storage mode based on the battery health indicator 205 and operational characteristics of the data storage system 204. In one embodiment, controller 210 implements a particular mode based on a status of data storage system 204. For example, the data storage mode can be implemented based on the battery health indicator 205 and an amount of data stored in one or more of disk stack 212, non-volatile cache 214, and RAM 216. In another example, controller 210 is configured to control implementation of various diagnostic or maintenance operations in the data storage system 204 based on the battery health indicator 205. For instance, controller 210 can be configured to prevent or limit certain activities in the data storage system 204 that require extensive power use (e.g., fly height calibration of a read/write head, servo runout adjustments, background defect scans, etc.) based on the battery health indicator 205. In one embodiment, if the battery health indicator 205 indicates a battery level below a particular level, controller 210 is configured to delay certain diagnostic and/or maintenance operations in data storage system 204. Controller 210 can be configured to delay such operations until the battery health indicator 205 indicates that the battery level has risen to a level above a threshold and/or the power source is switched to AC power, for example. Further, using multiple threshold levels certain activities can be delayed depending on a level of importance associated with the activities.

Further, some activities performed within the data storage system 204 (e.g. disc spin up, seek operations, high burst rates to buffer, etc.) can have large current excursions, which can cause system problems due to inability of the power source to supply required current bursts. In accordance with one embodiment, controller 210 is configured to efficiently limit peak current excursions which can operate to extend battery life and/or eliminate current peaks which can cause the power source to exceed voltage drop thresholds monitored by the host BIOS. For instance, in one embodiment the controller 210 can modify performance characteristics (e.g. spin up time, seek time) of the data storage system 204.

It is noted that elements described herein with respect to the battery health indicator can be implemented in hardware, software, firmware, and/or a combination thereof. For example, in one embodiment the battery health indicator 205 is processed and data storage modes are implemented using firmware in the data storage system.

FIG. 2B illustrates another embodiment of host 202 and data storage system 204. In the embodiment illustrated in FIG. 2B, battery health indicator 205 is passed from driver 230 of host 202 through a transport mechanism 206 to data storage system controller 210. As illustrated, the battery health indicator 205 is transmitted directly from driver 230 and is not transmitted through controller 220. It is noted that in other examples the battery health indicator 205 can be provided through transport mechanism 206 directly from host system BIOS 228 and/or operating system 224.

Battery health indicator 205 is transmitted using transport mechanism 206 and is, for example, separate from commands and data transmitted from host 202 over channel 203. In one example, the battery health indicator is received at interface 215 and is transmitted independently of data storage mode commands received from host 202. In one embodiment, transport mechanism 206 comprises one or more ports or pins of interface 217 that are separate from a number of ports or pins over which data and commands are transmitted on channel 203.

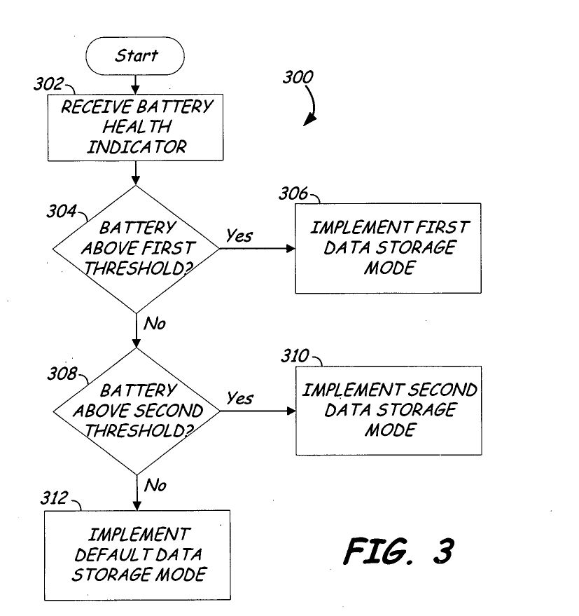

FIG. 3 is a flow diagram of a method 300 for implementing data storage modes based on the battery health indicator. At step 302, the battery health indicator is received. At step 304, the method determines whether the battery health indicator indicates that a level or status (i.e., a charge or energy of the power source, a voltage of the power source, a remaining discharge time, a discharge rate) is above a first threshold. In the embodiment illustrated in FIG. 3, the battery health indicator comprises a numerical value representing a percentage of power remaining in the power source.

Step 306 implements a first data storage mode. If the battery level is not above the first threshold, the method proceeds to step 308 where the method determines whether the battery level is above a second threshold. If so, the method implements a second data storage mode at step 310. Otherwise, the method can implement a default data storage mode at step 312.

It is noted that while FIG. 3 illustrates a first, a second, and a default data storage mode, any number of data storage modes can be implemented based on the battery health indicator. For example, any number of predefined thresholds can be established based on a number of data storage modes and/or power modes available in the data storage system. In one example, a number of predefined discrete thresholds can be mapped to host defined and/or commanded power modes.

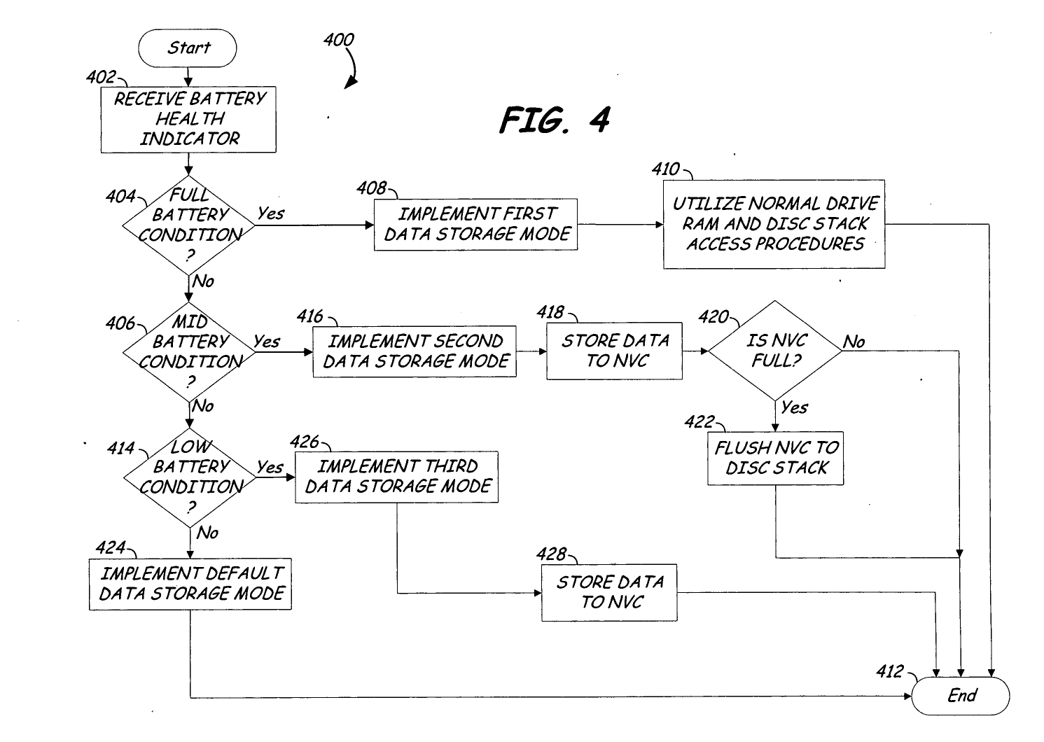

FIG. 4 illustrates a method 400 for implementing data storage modes using a battery health indicator. At step 402 the battery health indicator is received. At step 404, the method determines whether the battery health indicator indicates a full battery condition. For example, a full battery condition can be predefined as a battery health indicator above a first preselected threshold (e.g., 90%, 80%, 70%, etc.). If the battery health indicator indicates a full battery condition, the method proceeds to step 408 where a first data storage mode is implemented. In the illustrated embodiment, the first data storage mode comprises utilizing normal drive RAM and disk stack access procedures at step 410. To illustrate, in one example a “normal” disk stack access procedure can include providing data received by controller 210 over channel 203 to RAM 216 for storage to disk stack 212.

At step 406, the method 400 determines whether the battery health indicator indicates a mid-level battery condition. For example, a mid-level battery condition can be predefined as a battery health indicator within a preselected range. In one embodiment, a mid-level battery condition is defined as a battery health indicator indicating that a remaining battery level is within a predefined range (e.g., between 80% and 40%, between 70% and 30%, between 70% and 40%, etc.). If the battery health indicator indicates a mid-level battery condition at step 406, the method proceeds to step 416 where a second data storage mode is implemented. In the embodiment of FIG. 4, the second data storage mode includes storing the data to a non-volatile cache (such as non-volatile cache 214). At step 420, the second data storage mode determines whether the non-volatile cache is full (or above a threshold level). If so, the method proceeds to step 422 wherein the non-volatile cache can be flushed to the disk stack. In one example, the non-volatile cache is flushed by transferring the data in the non-volatile cache to the disk stack and reallocating the storage locations in the non-volatile cache for next portion(s) of data. The second data storage mode utilizes the non-volatile cache and can therefore reduce the number of disk stack access procedures and/or reduce an overall power consumption of the data storage system.

At step 414, the method determines whether a low battery condition exists. For example, a low battery condition can be predefined as a battery health indicator below a second preselected threshold (e.g., 30%, 20%, 10%, etc.). If the low battery condition exists, the method proceeds to step 426 wherein a third data storage mode is implemented. In the embodiment of FIG. 4, the third data storage mode comprises storing the data to the non-volatile cache at step 428. Step 428 utilizes the non-volatile cache and can minimize the number of disk stack access procedures and/or reduce an overall power consumption of the data storage system. In this example, data in the non-volatile cache is not flushed to the disc stack while the battery health indicator remains in the low battery condition. Data storage system controller 210 is configured to block or otherwise disable flushing operations while in the low battery condition.

The data stored to the non-volatile cache is later flushed from non-volatile cache to the disk stack when the controller 210 re-enables the flushing operation. For example, the data can be flushed from the non-volatile cache to the disc stack if the battery health indicator later indicates a different battery condition (e.g., full battery condition, mid-level battery condition). A default data storage mode can be implemented at step 424. For example, the default data storage mode at step 424 can comprise implementing the third data storage mode illustrated at step 426. In another example, a default data storage mode can comprise implementing a “normal” data storage mode, such as the mode described above with respect to step 408.

Referring again to FIGS. 2A and 2B, in one embodiment the battery health indicator 205 can be utilized by controller 210 to control write caching procedures within data storage system 204. For example, in one embodiment when write caching on the host 202 is enabled, data is sent to data storage system 204 and held in RAM 216 until a later time when the data in RAM 216 can be committed to disk stack 212. However, the data cached in RAM 216 can be susceptible to reliability and data integrity errors, for example in the event of a loss of power to the data storage system 204. In one embodiment, battery health indicator 205 is utilized by controller 210 to implement a write operation of the cached data to the disc stack 212. For example, controller 210 can be configured to flush cached data to the disc stack 212 if the battery health indicator 205 indicates a battery charge within a particular range. Further, controller 210 can utilize the battery health indicator 205 to control the amount of data held in RAM 216. For example, controller 210 can gradually reduce the amount of space allocated in RAM 216 for caching data from host 202 to provide adequate battery margin and ensure that an amount of power remaining is adequate to commit the data in RAM 216 to disk stack 212. Moreover, controller 210 can implement and control the write caching procedures discussed above based upon the battery health indicator 205 and does not require specific commands from the host 202 and does not require that flush or commit commands are transmitted from host 202.

It is noted that the above-described embodiments illustrate examples of data storage modes that can be implemented in a data storage system based on a battery health indicator. Other types and configurations of data storage modes are also within the scope of the concepts described herein. Further, it is also noted that a data storage system can also be configured to implement data retrieval modes based on a battery health indicator.

It is to be understood that even though numerous characteristics and advantages of various embodiments of the invention have been set forth in the foregoing description, together with details of the structure and function of various embodiments of the disclosure, this disclosure is illustrative only, and changes may be made in detail, especially in matters of structure and arrangement of parts within the principles of the present disclosure to the full extent indicated by the broad general meaning of the terms in which the appended claims are expressed. For example, the particular elements may vary depending on the particular application for the system or method while maintaining substantially the same functionality without departing from the scope and spirit of the present disclosure and/or the appended claims.

What is claimed is:

1. A data storage system comprising:
an input interface configured to receive data and a battery health indicator;
at least one data storage device; and
a controller configured to store data in the at least one data storage device and configured to implement a data storage mode based on the battery health indicator.

2. The data storage system of claim 1, wherein the controller is communicatively coupled to a host system through the input interface to receive the data and battery health indicator from the host system.

3. The data storage system of claim 2, wherein the host system includes an exhaustible power source that is configured to provide power to the data storage system.

4. The data storage system of claim 3, wherein the battery health indicator comprises an indication of a percentage of remaining power in the exhaustible power source.

5. The data storage system of claim 2, wherein the battery health indicator is received separately from commands and user data received from the host system.

6. The data storage system of claim 5, wherein the battery health indicator is received at the controller over a communication path that is different than a communication path over which the commands and user data are received at the controller.

7. The data storage system of claim 2, wherein a data command associated with the data comprises a first command structure and the battery health indicator comprises a second command structure, the first and second command structures being different.

8. The data storage system of claim 2, wherein the input interface comprises a SATA interface, and wherein the battery health indicator comprises at least a portion of a vendor unique SATA command received at the SATA interface.

9. The data storage system of claim 2, wherein the battery health indicator is provided to the controller directly from a system BIOS of the host system.

10. The data storage system of claim 2, wherein the controller selects a particular data storage mode from a plurality of predefined modes based on the battery health indictor.

11. The data storage system of claim 10, wherein the controller selects a first of the modes if the battery health indicator indicates that the level of power in the exhaustible power source is above a first threshold and selects a second of the modes if the battery health indicator is below a second threshold, the first and second thresholds being different.

12. The data storage system of claim 1, wherein the controller implements the data storage mode based on the battery health indicator and an operational characteristic of the data storage system, the operational characteristic comprises at least one characteristic selected from the group consisting of an amount of data stored in the at least one data storage device, a disc spin up time, a track seek time, and a buffer burst rate.

13. A controller in a data storage system, the controller comprising:
an input configured to receive data and a battery health indicator from a host device, wherein the battery health indicator is indicative of a level of power in an exhaustible power source; and
a processing component configured to adjust a data storage mode based on the battery health indicator received from the host device.

14. The controller of claim 13, wherein the battery health indicator comprises a percentage of power remaining in the exhaustible power source, the exhaustible power source being configured to supply operating power to the data storage system.

15. The controller of claim 13, wherein the controller is configured to select a particular data storage mode from a plurality of predefined modes based on the battery health indicator.

16. The controller of claim 13, wherein the battery health indicator is received independently of commands received from an operating system of the host system.

17. A method for storing data in a data storage system, the method comprising:
receiving an indication from a host device of a level of power in an exhaustible power source;
implementing a data storage mode based on the indication;
receiving data from the host device; and
storing the data to at least one data storage medium in the data storage system based on the data storage mode.

18. The method of claim 17, wherein the indication comprises a battery health indicator indicative of a percentage of remaining power in the exhaustible power source.

19. The method of claim 17, and further comprising receiving a write command for the data from the host device, wherein the indication is received over a separate communication path.

20. The method of claim 17, and further comprising selecting a particular data storage mode from a plurality of predefined modes based on the indication, wherein selecting comprises:
selecting a first mode if the battery health indicator indicates that the level of power in the exhaustible power source is above a first threshold; and
selecting a second mode if the battery health indicator is below a second threshold, the first and second thresholds being different.
